(19) United States
(12) Patent Application Publication
(10) Pub. No.: US 2026/0359533 A1
(43) Pub. Date: Nov. 12, 2026

(54) CONFIGURATION OF ELECTRONIC DESIGN AUTOMATION SYSTEMS

(71) Applicant: INTERNATIONAL BUSINESS MACHINES CORPORATION, Armonk, NY (US)

(72) Inventors: Eduard Herkel, Stuttgart (DE); Florian Braun, Albbruck (DE); Julian Stefanac, Bargfeld-Stegen (DE)

(21) Appl. No.: 19/256,492

(22) Filed: Jul. 1, 2025

(30) Foreign Application Priority Data
May 8, 2025 (GB) 2507007.9

(51) Int. Cl. G06F 30/323

(52) U.S. Cl. CPC G06F 30/323

(57) ABSTRACT

Disclosed herein is a method of integrated circuit manufacturing using an Electronic Design Automation system, configured using key value pairs, to provide a physical integrated circuit. The method includes receiving a logical design of the integrated circuit. The logical design includes multiple building blocks that include the key value pairs. The method also includes parsing the at least one data source to provide an initial data structure with the key value pairs. The data structure provides the key value pairs divided into duplicate key value pairs, utilized key value pairs, and ignored key value pairs. The method also includes assigning, for each duplicate key value pair in the duplicate key value pairs, a first portion of duplicate key value pairs to the utilized key value pairs and a remaining portion of the duplicate key value pairs to the ignored key value pairs, and providing the utilized key value pairs.

### BACKGROUND

This disclosure relates generally to synthesis of physical designs for integrated circuits, and in particular to the configuration of Electronic Design Automation systems.

The physical design synthesis of integrated circuits (ICs) is the process of transforming a circuit's logical representation into a physical layout that can be fabricated. This involves partitioning, placement, routing, and optimization to meet performance, power, timing, and other constraints. The physical design of an integrated circuit may be generated by inputting a logical design of the integrated circuit into an Electronic Design Automation system. An Electronic Design Automation system may be a complex collection of software tools that work together to generate the physical design. Various portions of a logical design of the integrated circuit may contain so called key value pairs which define values or parameters used to configure and control the behavior of the Electronic Design Automation system.

### SUMMARY

Embodiments in accordance with the present invention disclose a method, computer program product and computer system for integrated circuit manufacturing. The method, computer program product and computer system can receive a logical design of at least a part of an integrated circuit, where the logical design comprises multiple building blocks, where the logical design is provided in at least one data source, where the building blocks include key value pairs. The method, computer program product and computer system can parse the at least one data source to provide an initial data structure with the key value pairs, where the data structure provides the key value pairs divided into duplicate key value pairs, utilized key value pairs, and ignored key value pairs. The method, computer program product and computer system can assign, for each duplicate key value pair in the duplicate key value pairs, a first portion of duplicate key value pairs to the utilized key value pairs and a remaining portion of the duplicate key value pairs to the ignored key value pairs. The method, computer program product and computer system can provide the utilized key value pairs as a second data structure.

### BRIEF DESCRIPTION OF THE SEVERAL VIEWS OF THE DRAWINGS

In the following embodiments of the invention are explained in greater detail, by way of example only, referring to the drawings in which.

FIG. 1 illustrates an example of a computing environment, in accordance with an embodiment of the present invention.

FIG. 2 depicts a cloud computing environment according to an example of the present invention.

FIG. 3 depicts an abstraction model layers according to an example of the present invention.

FIG. 4 shows a further view of the computing environment, in accordance with an embodiment of the present invention.

FIG. 5 illustrates a method of using the computing environment of FIG. 4, in accordance with an embodiment of the present invention.

FIG. 6 shows a further view of the computing environment, in accordance with an embodiment of the present invention.

FIG. 7 illustrates a method of using the computing environment of FIG. 6, in accordance with an embodiment of the present invention.

FIG. 8 illustrates an example of a user interface used to display and edit the key value pairs, in accordance with an embodiment of the present invention.

FIG. 9a shows a means of supplying the key value pairs for the user interface in FIG. 8 using a data source-based parsing method, in accordance with an embodiment of the present invention.

FIG. 9b shows a parsing of the parameter data sources, in accordance with an embodiment of the present invention.

FIG. 9c shows the parsing of the parameter data sources in further details, in accordance with an embodiment of the present invention.

FIG. 10 illustrates a further example of a user interface used to display and edit the key value pairs, in accordance with an embodiment of the present invention.

FIG. 11 shows a flowchart which illustrates a method of supplying the key value pairs for the user interface of FIG. 10 using a precedence configuration data source, in accordance with an embodiment of the present invention.

### DETAILED DESCRIPTION

Detailed embodiments of the claimed structures and methods are disclosed herein; however, it can be understood that the disclosed embodiments are merely illustrative of the claimed structures and methods that may be embodied in various forms. This invention may, however, be embodied in many different forms and should not be construed as limited to the exemplary embodiments set forth herein. In the description, details of well-known features and techniques may be omitted to avoid unnecessarily obscuring the presented embodiments. It is to be understood that the singular forms “a,” “an,” and “the” include plural referents unless the context clearly dictates otherwise. Thus, for example, reference to “a component surface” includes reference to one or more of such surfaces unless the context clearly dictates otherwise.

The descriptions of the various embodiments of the present invention will be presented for purposes of illustration but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

In one aspect a method of integrated circuit manufacturing using an Electronic Design Automation system to provide a physical integrated circuit design of an integrated circuit is disclosed. An Electronic Design Automation system, as used herein, encompasses a software tool or a group of software tools which can be used to take a logical design of an integrated circuit and provide the physical integrated circuit design for that logical design. The physical integrated circuit design contains such things as the mask design and the actual layout of different layers and manufacturing details of the physical integrated circuit design. When one has a physical integrated circuit design one is for example able to order masks and/or go to an integrated circuit foundry and have the integrated circuit manufactured. The key value pairs are values which are used to configure the operation of the various software or software tools that make up the Electronic Design Automation system.

There may be a variety of key value pairs used to configure the Electronic Design Automation system. In one example the key value pairs are a size or default size of a predesigned block. For example, the name or label in the key value pair could be “size” and the value could be the default size of a predesigned block. When integrated circuits are designed complete building blocks provided by designers may be used or incorporated into the design. These predesigned blocks are commonly referred to as intellectual property (IP) blocks. An example of a predesigned block could be a SRAM cell. Often times the predesigned blocks may be modified or provided at a later stage in the design process which may result in changed requirements for the physical design synthesis of the integrated circuit. Key value pairs may be used to specify the size of a particular predesigned block or a default sized for a predesigned block to enable their incorporation, possibly later in the design process, into the final integrated circuit design.

Other examples of key value pairs which may be specified may include, but are not limited to: preliminary placement information for design structures or elements, cycle time, placement information, layer assignments, cost functions, settings for optimization routines, turning on or off specific optimization routines, resource settings, resource settings for threads, resource settings for requested memory, placement assumptions for building blocks, blockage locations, and combinations thereof. A key may be a certain property of the EDA system, for example the key might be anyone of the above mentioned. The key could be placement information, and the value reflects the “size” of the key.

The method comprises receiving a logical design of at least a part of the integrated circuit. The logical design could for example be for the entire integrated circuit or only a portion of the integrated circuit, which is desired to be modeled, for example, a critical signal path within the integrated circuit. The logical design is provided in at least one data source. The at least one data source, as used herein, encompasses data sources or data which is provided as the logical design.

There may for example be an overall logical design which then uses the so-called multiple building blocks or macros to explain or detail further portions of the integrated circuit. Often times, the logical design may be at a high level and then the various components or building blocks, which make up the logical design, are then provided as preassembled components which are then assembled to make the physical integrated circuit design. The building blocks comprise at least some of the key value pairs. The building blocks comprising at least some of the key value pairs could be literal in the sense that the key value pairs are contained within the building block or they could be associated with the building block, for example located in an associated configuration data source or database. The key value pairs represent configuration data for the various software tools of the Electronic Design Automation system.

The at least one data source may each store or comprise some of the key value pairs and, as was mentioned, these data sources may reference building blocks, which they themselves also contain key value pairs. The at least one data source may literally store or comprise some of the key value pairs or it may logically be associated with other data sources that store or comprise some of the key value pairs. Parsing the at least one data source may refer to literally parsing the at least one data source or parsing configuration data or files logically associated with the at least one data source.

In some examples, the same key value pair may be defined more than once, for example, it may be defined within multiple or the at least one data source and it may also be defined multiple times within the multiple building blocks. A difficulty that arises because of this is that the definition of the key value pairs in different locations may be duplicated or have different values. This provides a problem when running the Electronic Design Automation system in that it may be indeterminate which of the key value pairs to use. There may for example be a hierarchy to the at least one data source, where the key value pairs within a particular data source are given precedence and also amongst the multiple building blocks. Additionally, the multiple definitions of the saved key value pairs in different locations may be difficult or impossible for a user to manage or understand.

For example, if a building block uses sub-building blocks the main or calling building block may have a higher precedence level for its key value pairs. This may cause problems though because the value of the key value pairs may in some instances depend upon the order in which the at least one data source are parsed by the Electronic Design Automation system. When there are duplicate definitions of key value pairs, examples may provide a means of determining which of these duplicate key value pairs to use and thus provide a more deterministic behavior of the Electronic Design Automation system.

The method further comprises parsing the at least one data source to provide an initial data structure with the key value pairs. The data structure provides the key value pairs divided into duplicate key value pairs, utilized key value pairs, and ignored key value pairs. During this parsing the key value pairs are divided into three groups. The duplicate key value pairs are key value pairs which have been parsed more than once from more than one source and are duplicates. In the duplicate key value pairs, each key value is assigned more than one value. The duplicate key value pairs in some examples is a list or collection of the key value pairs which are duplicated and may be resolved.

The utilized key value pairs are the ones that are used for configuring the Electronic Design Automation system when it is used to generate the physical integrated circuit design. The ignored key value pairs are key value pairs which are not used or ignored by the Electronic Design Automation system. For example, if there are duplicate key value pairs then one of them may be selected and assigned to the mandatory key value pairs and the remaining of them are then assigned to the ignored key value pairs. This has the effect of having only a single key value in each of the utilized key value pairs and then using this for configuring and running the Electronic Design Automation system.

The method further comprises assigning, for each duplicate key value pair in the duplicate key value pairs, a first portion of duplicate key value pairs to the utilized key value pairs and a remaining portion of the duplicate key value pairs to the ignored key value pairs. In this step, the duplicate key value pairs, which represent the same key with different values, are then sorted further. One of them is assigned to the utilized key value pairs, where it is then available for use for configuring the Electronic Design Automation system and the other of the duplicate key values pairs, where one key has, several values are then assigned to the ignored key value pairs, and they are not used when the Electronic Design Automation system is configured.

The method further comprises providing the utilized key value pairs as a second data structure for use by the Electronic Design Automation system. In this step, the second data structure is provided, for example, for configuring the Electronic Design Automation system. As will be detailed below, there are several ways of doing this. In one case, the Electronic Design Automation system could simply read the second data structure and use the collected utilized key value pairs for its configuration. Any values in the ignored key value pair would then be ignored. Another way to proceed would be to take the utilized key value pairs and then write them to the at least one data source, replacing the values which are in the ignored key value pairs. This may for example be more time consuming but may for example have the advantage that it would not require a re-write or adjustment of the software tools for the Electronic Design Automation system. In general, this example has the benefit in that the execution of the Electronic Design Automation system may be more consistent.

For example, if there is an update to a software component that makes up the Electronic Design Automation system, it may change the order in which the at least one data source is parsed. This could have an effect that after a software update, the behavior of the Electronic Design Automation system changes and there are changes in the results when the physical integrated circuit design is generated. Using the second data structure to configure the Electronic Design Automation system may remove this possible change in the configuration or behavior of the Electronic Design Automation system.

In another example, providing the utilized key value pairs comprises storing the utilized key value pairs from the second data structure back to the at least one data source of the logical design or data source associated with the logical design. In this example, the values in the utilized key value pairs are used to replace duplicate key value pairs. This prevents the configuration of the Electronic Design Automation system from being indefinite.

In another example the assigning, for each duplicate key value pair in the duplicate key value pairs, a first portion of duplicate key value pairs to the utilized key value pairs and a remaining portion of the duplicate key value pairs to the ignored key value pairs is at least partially provided by a recommender algorithm.

A recommender algorithm for assigning key-value pairs to utilized or ignored categories can be implemented using a combination of rule-based logic and machine learning techniques. Initially, a set of predefined rules can be established based on domain-specific knowledge, ensuring that commonly required key-value pairs are assigned to the utilized set. These rules may consider factors such as data relevance, frequency of occurrence, and predefined constraints.

To enhance adaptability, a machine learning model, such as a decision tree or a neural network, can be trained on historical data where key-value pairs have been categorized. Features such as the semantic similarity of keys, value distributions, and contextual relevance can be extracted to improve the model's accuracy. A hybrid approach, combining rule-based filtering with AI-driven recommendations, can dynamically adjust to new data patterns, improving the classification process over time.

In another example, providing the utilized key value pairs comprises using the second data structure to at least partially override a configuration of the Electronic Design Automation system. In this example, instead of allowing the Electronic Design Automation system to read the key value pairs from the at least one data source, its behavior is instead changed so that the configuration is done using the second data structure. This, for example, may provide for better control of the Electronic Design Automation system.

In another example, assigning, for each duplicate key value pair in the duplicate key value pairs, a first portion of duplicate key value pairs to the utilized key value pairs and a remaining portion of the duplicate key value pairs to the ignored key value pairs is at least partially received from a graphical user interface that displays the duplicate key value pairs, utilized key value pairs, and the ignored key value pairs. In this example, a user is for example able to actively select and assign the key value pairs to different groups. In some examples, for example an artificial intelligence may be used to suggest which of the duplicate key value pairs should be assigned to the utilized key value pairs and the ignored key value pairs.

In another example, the graphical user interface is configured for any one of the following operations: the first operation is to receive a selection from the graphical user interface to change the value of the selected key value pair. The next possible operation is receiving a selection from the graphical user interface to include at least one additional key value pair. For example, it may be used to edit and add a key value pair which was not parsed. The next possible operation is to receive a selection from the graphical user interface to delete a selected key value pair. This enables further editing of the key value pairs that were parsed. The operations further comprise storing a selection of the key value pairs in a database or data source system in response to receiving the selection of the key value pairs from the graphical user interface. For example, the second data structure can be stored to a data source for further use or may also be stored in a database.

In another example, the parsing of the at least one data source to provide the initial data structure within the key value pairs comprises comparing the key value pairs to a precedence configuration data structure. In this example, the key value pairs are compared to a precedence configuration data structure which tells what precedence level a particular key value pair has according to the data source or building block that it came from. This may be advantageous because using the precedence configuration data structure enables very fine control or configuration of how the key value pairs are assigned to the different groups. Precedence means that the same key value pair may be defined (with same or different values) in different locations that might have different precedence levels. The Electronic Design Automation system may use the values from the key value pair that is stored with the highest precedence level values that have a lower precedence level are ignored. If a value is defined in the second-highest precedence level, but there is no value in the highest precedence level, the value may be fetched from the second highest level.

In another example, the parsing of the at least one data source to provide the initial data structure with the key value pairs comprises fetching a parameter scope for the at least one data source. For example, the at least one data source may have a location where the parameters or key value pairs are stored. The parameter scope may be a pointer to where the key value pairs are stored for a particular data source. The parsing of the at least one data source to provide the initial data structure with the key value pairs further comprises constructing a path to look for data structures for the parameter scope for the at least one data source.

The parsing of the at least one data source to provide the initial data structure with the key value pairs further comprises adding the key value parameters from the parameter data structures if the parameter data structures exist, for example, there may not be any parameters at the particular path or location where the key value pairs are stored. The unique key value parameters of the parameter data structures are added to the utilized key value pairs. When parsed, there may for example be key value parameters which are not present in any of the existing three groups of key value pairs. These are added directly to the utilized key value pairs. The duplicate key value parameters of the parameter data structures are added to the ignored key value pairs.

In one example, if a key value pair has exactly a same value and precedence level as one that's already in one of the three different groups of key value pairs, then it is able to be deleted, if it has a different precedence level than it could be kept. In a third case, when one of the matching pre-existing key value pairs in the utilized key value pairs and a newly parsed pre-existing key value pair and the parameter data structures match, they are then assigned such that one of them is assigned to the utilized key value pairs and the other of the matching is assigned to the duplicate key value pairs. For example, there may be a situation where a particular key value pair is already in the duplicate or utilized key value pairs. It may however be that the key has a different value. In this case, one of them is assigned to the utilized and the other one is assigned to the ignored key value pairs.

Then the method further provides proceeding to a next data source of the at least one data source if the parameter data structure does not exist. For example, the system does not find anything at the particular path or location. This example may be beneficial because it may provide for a means of determining which key value pairs are in the duplicate key value pairs, the utilized key value pairs, and the ignored key value pairs on the fly.

In another example, the parameter data structures have a hierarchy. The hierarchy of the matching pre-existing key value pairs in the utilized key value pairs and the newly parsed pre-existing key value pairs with the hierarchy is assigned to the utilized key value pairs. So, in this example, the source of the particular key value pairs has a hierarchy. This could be based on the particular data source that it is stored in. This hierarchy which exists for the data sources is then essentially transferred to the key value pairs and then used to sort them so that the key value pairs are all in the utilized key value pairs or the ignored key value pairs. This may provide for a way of automatically sorting the key value pairs into the different groups of key value pairs.

The hierarchy of the parameter data structure can come from several different sources. The physical design of the integrated circuit is hierarchical. The design may be defined in functional blocks or macros, which they themselves may have sub macros or sub functional blocks. In one example, the hierarchy of the key value pairs is derived from the hierarchy of the integrated circuit design and the design's hierarchy is used for the sorting of the key value pairs. In other cases, the hierarchy may be explicitly assigned using a precedence level. For example, there may be a precedence level configuration file or database which is used to assign an explicit precedence level to a particular macro or functional block.

In another example, receiving the selection of the duplicate key value pairs comprises analyzing at least one data source to sort the key value pairs into the duplicate key value pairs, the utilized key value pairs, and the ignored key value pairs. This analysis may for example be performed on the basis of output from an expert system, the use of rules, neural networks may for example be used for sorting them and also, as is mentioned above, it may be sorted based on a hierarchy of where the key value pair comes from.

In another example, the method further comprises extracting the key value pairs from the multiple data sources. The method further comprises sorting the multiple data sources based on the analysis to sort the key value pairs. So, in this case, the multiple data sources are then sorted, and a precedence level may be assigned and then this is used to sort of the key value pairs. This may for example be a good way of automatically sorting the key value pairs.

In another example, the analysis comprises identifying if at least two different parameter sets have been created with almost the same parameter set for a same or different building block of the multiple building blocks. For example, if a particular value for a key value pair is within a predetermined threshold, then they may be considered to be identical. This may for example be useful in avoiding situations where the representation of a key value pair is extremely close or essentially the same. This may provide for a better sorting of the key value pairs.

In another example, the analysis further comprises identifying and resolving possible conflicts between different key value parameter sets belonging to the same building block of the multiple building blocks. For example, a particular building block may be made up of sub-building blocks or macros. Within these different components within a particular building block, the same key value pair may be defined with different values in different locations. The resolution of these conflicts may be beneficial because it may provide for a more deterministic synthesis of the physical design of the integrated circuit.

In another example, the logical design of the at least part of the integrated circuit is a critical signal path of an overall logical design of the integrated circuit. A critical signal path, as used herein, encompasses a signal path or circuit which has strict or critical timing requirements. For example, in the overall logical design certain portions of the overall logical design may have critical timing functionality and may therefore be a limitation on the designability and manufacturability of the overall logical design. In this example, just the critical signal path from the overall logical design is used.

This may have the benefit of being able to work out how the critical signal path can be constructed before performing the physical design of the overall logical design. This may for example enable more and quicker iterations in determining such things a configuration data for the Electronic Design Automation system. The method further comprises generating a preliminary physical design of the critical signal path using the Electronic Design Automation system. The Electronic Design Automation system is configured using the second data structure during generation of the preliminary physical design. The method further comprises providing the preliminary physical design of the critical signal path. The preliminary physical design may for example be used as input to simulations and a test of this critical timing functionality of the critical signal path in advance.

In another example, the logical design of the at least part of the integrated circuit is an overall logical design of the integrated circuit. The overall logical design, as used herein, encompasses a complete or fully functional logical design of the integrated circuit. When the overall logical design is used to generate the physical design of the integrated circuit, it will therefore be a functional or fully functional design.

In another example, the method further comprises generating the physical integrated circuit by inputting the overall logical design as input to the Electronic Design Automation system. The Electronic Design Automation system is configured using the second data structure during generation of the physical integrated circuit design. The preliminary physical design is preferably used as an input to the Electronic Design Automation system during generation of the physical integrated circuit design. The preliminary physical design of the critical signal path may therefore be optionally used as a starting point or for further configuration of the Electronic Design Automation system. This may, in some examples, have the effect of accelerating the generation of the physical design of the overall logical design.

The method further comprises manufacturing an integrated circuit using the physical integrated circuit design. This may for example incorporate such things as using the physical integrated circuit design to order masks and/or to send an order to a foundry or other semiconductor fabrication site to manufacture the integrated circuit. This may be advantageous because integrated circuits manufactured using these designs may have higher quality because the control over the key value pairs is greater. Another potential benefit is that the operating of the Electronic Design Automation system may become more transparent and deterministic.

In another example, the method further comprises flattening the multiple building blocks during parsing of the at least one data source. As was mentioned before, a building block is essentially a built up structure that is macro-like and is used for constructing the physical integrated circuit design. Often times, the building blocks themselves are made up of sub-building blocks. The process of flattening is basically in taking all of the sub-components of a building block and flushing it out so that the entire design is specified as the design itself and not as a hierarchy of building blocks. This may have the benefit of ensuring that all of the relevant key value pairs are parsed or harvested.

In another example, the method of providing the second data structure for an Electronic Design Automation system is performed by a separate software tool of the Electronic Design Automation system. In this example, instead of having the functionality incorporated into existing software tools, a completely separate software tool may be used for performing these method steps and functionality. This may have the benefit of not needing to modify the code or structures of the existing Electronic Design Automation system. This may for example lead to better quality control of the software and better performance.

In another example, there is a computer program product comprising a computer-readable storage medium having computer-readable program code embedded therewith. The computer-readable program code is configured to implement an example of a method as detailed above. The benefit of the execution of these methods by the computer program product have been previously discussed.

In another aspect, there is a computer system. The computer system comprises a processor configured for controlling the computer system. The computer system further comprises a memory storing computer-readable program code configured for implementing an Electronic Design Automation system. The execution of said computer-readable program code causes the processor to receive a logical design of at least a part of an integrated circuit. The logical design comprises multiple building blocks. The logical design is provided in at least one data source.

The building blocks comprise at least some of the key value pairs. Execution of the computer-readable program code further causes the processor to parse the at least one data source to provide an initial data structure with the key value pairs. The data structure provides the key value pairs divided into duplicate key value pairs, utilized key value pairs, and ignored key value pairs. The execution of the computer-readable program code further causes the processor to receive a selection for each duplicate key value pair in the duplicate key value pairs assigning one of the duplicate key value pairs to the utilized key value pairs and the remaining of the duplicate key value pairs to the ignored key value pairs. Execution of the computer-readable program code further causes the processor to provide the utilized key value pairs as a second data structure for use or for configuration by the Electronic Design Automation system. Circuit.

Various aspects of the present disclosure are described by narrative text, flowcharts, block diagrams of computer systems and/or block diagrams of the machine logic included in computer program product (CPP) embodiments. With respect to any flowcharts, depending upon the technology involved, the operations can be performed in a different order than what is shown in a given flowchart. For example, again depending upon the technology involved, two operations shown in successive flowchart blocks may be performed in reverse order, as a single integrated step, concurrently, or in a manner at least partially overlapping in time.

A computer program product embodiment (“CPP embodiment” or “CPP”) is a term used in the present disclosure to describe any set of one, or more, storage media (also called “mediums”) collectively included in a set of one, or more, storage devices that collectively include machine readable code corresponding to instructions and/or data for performing computer operations specified in a given CPP claim. A “storage device” is any tangible device that can retain and store instructions for use by a computer processor. Without limitation, the computer-readable storage medium may be an electronic storage medium, a magnetic storage medium, an optical storage medium, an electromagnetic storage medium, a semiconductor storage medium, a mechanical storage medium, or any suitable combination of the foregoing. Some known types of storage devices that include these mediums include: diskette, hard disk, random access memory (RAM), read-only memory (ROM), erasable programmable read-only memory (EPROM or Flash memory), static random access memory (SRAM), compact disc read-only memory (CD-ROM), digital versatile disk (DVD), memory stick, floppy disk, mechanically encoded device (such as punch cards or pits/lands formed in a major surface of a disc) or any suitable combination of the foregoing. A computer-readable storage medium, as that term is used in the present disclosure, is not to be construed as storage in the form of transitory signals per se, such as radio waves or other freely propagating electromagnetic waves, electromagnetic waves propagating through a waveguide, light pulses passing through a fiber optic cable, electrical signals communicated through a wire, and/or other transmission media. As will be understood by those of skill in the art, data is typically moved at some occasional points in time during normal operations of a storage device, such as during access, de-fragmentation or garbage collection, but this does not render the storage device as transitory because the data is not transitory while it is stored.

Computing environment 100 contains an example of an environment for the execution of at least some of the computer code involved in performing the inventive methods, such as code for implementing an Electronic Design Automation system 400. In addition to Electronic Design Automation system 400, computing environment 100 includes, for example, computer 101, WAN 102, EUD 103, remote server 104, public cloud 105, and private cloud 106. In this embodiment, computer 101 includes processor set 110 (including processing circuitry 120 and cache 121), communication fabric 111, volatile memory 112, persistent storage 113 (including operating system 122 and Electronic Design Automation system 400, as identified above), peripheral device set 114 (including user interface (UI) device set 123, storage 124, and Internet of Things (IoT) sensor set 125), and network module 115. Remote server 104 includes remote database 130. Public cloud 105 includes gateway 140, cloud orchestration module 141, host physical machine set 142, virtual machine set 143, and container set 144.

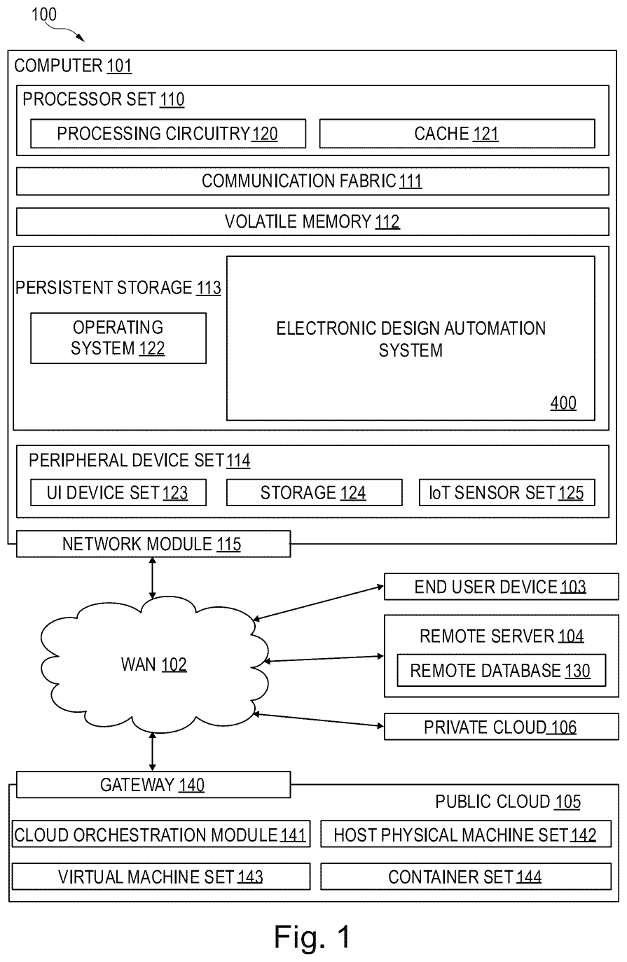

Computer 101 may take the form of a desktop computer, laptop computer, tablet computer, smart phone, smart watch or other wearable computer, mainframe computer, quantum computer or any other form of computer or mobile device now known or to be developed in the future that is capable of running a program, accessing a network or querying a database, such as remote database 130. As is well understood in the art of computer technology, and depending upon the technology, performance of a computer-implemented method may be distributed among multiple computers and/or between multiple locations. On the other hand, in this presentation of computing environment 100, detailed discussion is focused on a single computer, specifically computer 101, to keep the presentation as simple as possible. Computer 101 may be located in a cloud, even though it is not shown in a cloud in FIG. 1. On the other hand, computer 101 is not required to be in a cloud except to any extent as may be affirmatively indicated.

Processor set 110 includes one, or more, computer processors of any type now known or to be developed in the future. Processing circuitry 120 may be distributed over multiple packages, for example, multiple, coordinated integrated circuit chips. Processing circuitry 120 may implement multiple processor threads and/or multiple processor cores. Cache 121 is memory that is located in the processor chip package(s) and is typically used for data or code that should be available for rapid access by the threads or cores running on processor set 110. Cache memories are typically organized into multiple levels depending upon relative proximity to the processing circuitry. Alternatively, some, or all, of the cache for the processor set may be located “off chip.” In some computing environments, processor set 110 may be designed for working with qubits and performing quantum computing.

Computer-readable program instructions are typically loaded onto computer 101 to cause a series of operational steps to be performed by processor set 110 of computer 101 and thereby effect a computer-implemented method, such that the instructions thus executed will instantiate the methods specified in flowcharts and/or narrative descriptions of computer-implemented methods included in this document (collectively referred to as “the inventive methods”). These computer-readable program instructions are stored in various types of computer-readable storage media, such as cache 121 and the other storage media discussed below. The program instructions, and associated data, are accessed by processor set 110 to control and direct performance of the inventive methods. In computing environment 100, at least some of the instructions for performing the inventive methods may be stored with Electronic Design Automation system 400 in persistent storage 113.

Communication fabric 111 is the signal conduction path that allows the various components of computer 101 to communicate with each other. Typically, this fabric is made of switches and electrically conductive paths, such as the switches and electrically conductive paths that make up buses, bridges, physical input/output ports and the like. Other types of signal communication paths may be used, such as fiber optic communication paths and/or wireless communication paths.

Volatile memory 112 is any type of volatile memory now known or to be developed in the future. Examples include dynamic type random access memory (RAM) or static type RAM. Typically, volatile memory 112 is characterized by random access, but this is not required unless affirmatively indicated. In computer 101, the volatile memory 112 is located in a single package and is internal to computer 101, but, alternatively or additionally, the volatile memory may be distributed over multiple packages and/or located externally with respect to computer 101.

Persistent storage 113 is any form of non-volatile storage for computers that is now known or to be developed in the future. The non-volatility of this storage means that the stored data is maintained regardless of whether power is being supplied to computer 101 and/or directly to persistent storage 113. Persistent storage 113 may be a read only memory (ROM), but typically at least a portion of the persistent storage allows writing of data, deletion of data and re-writing of data. Some familiar forms of persistent storage include magnetic disks and solid state storage devices. Operating system 122 may take several forms, such as various known proprietary operating systems or open source Portable Operating System Interface-type operating systems that employ a kernel. The code included with Electronic Design Automation system 400 typically includes at least some of the computer code involved in performing the inventive methods.

Peripheral device set 114 includes the set of peripheral devices of computer 101. Data communication connections between the peripheral devices and the other components of computer 101 may be implemented in various ways, such as Bluetooth connections, Near-Field Communication (NFC) connections, connections made by cables (such as universal serial bus (USB) type cables), insertion-type connections (for example, secure digital (SD) card), connections made through local area communication networks and even connections made through wide area networks such as the internet. In various embodiments, UI device set 123 may include components such as a display screen, speaker, microphone, wearable devices (such as goggles and smart watches), keyboard, mouse, printer, touchpad, game controllers, and haptic devices. Storage 124 is external storage, such as an external hard drive, or insertable storage, such as an SD card. Storage 124 may be persistent and/or volatile. In some embodiments, storage 124 may take the form of a quantum computing storage device for storing data in the form of qubits. In embodiments where computer 101 is required to have a large amount of storage (for example, where computer 101 locally stores and manages a large database) then this storage may be provided by peripheral storage devices designed for storing very large amounts of data, such as a storage area network (SAN) that is shared by multiple, geographically distributed computers. IoT sensor set 125 is made up of sensors that can be used in Internet of Things applications. For example, one sensor may be a thermometer, and another sensor may be a motion detector.

Network module 115 is the collection of computer software, hardware, and firmware that allows computer 101 to communicate with other computers through WAN 102. Network module 115 may include hardware, such as modems or Wi-Fi signal transceivers, software for packetizing and/or de-packetizing data for communication network transmission, and/or web browser software for communicating data over the internet. In some embodiments, network control functions and network forwarding functions of network module 115 are performed on the same physical hardware device. In other embodiments (for example, embodiments that utilize software-defined networking (SDN)), the control functions and the forwarding functions of network module 115 are performed on physically separate devices, such that the control functions manage several different network hardware devices. Computer-readable program instructions for performing the inventive methods can typically be downloaded to computer 101 from an external computer or external storage device through a network adapter card or network interface included in network module 115.

WAN 102 is any wide area network (for example, the internet) capable of communicating computer data over non-local distances by any technology for communicating computer data, now known or to be developed in the future. In some embodiments, the WAN 102 may be replaced and/or supplemented by local area networks (LANs) designed to communicate data between devices located in a local area, such as a Wi-Fi network. The WAN 102 and/or LANs typically include computer hardware such as copper transmission cables, optical transmission fibers, wireless transmission, routers, firewalls, switches, gateway computers and edge servers.

End User Device (EUD 103) is any computer system that is used and controlled by an end user (for example, a customer of an enterprise that operates computer 101) and may take any of the forms discussed above in connection with computer 101. EUD 103 typically receives helpful and useful data from the operations of computer 101. For example, in a hypothetical case where computer 101 is designed to provide a recommendation to an end user, this recommendation would typically be communicated from network module 115 of computer 101 through WAN 102 to EUD 103. In this way, EUD 103 can display, or otherwise present, the recommendation to an end user. In some embodiments, EUD 103 may be a client device, such as thin client, heavy client, mainframe computer, desktop computer and so on.

Remote Server 104 is any computer system that serves at least some data and/or functionality to computer 101. Remote server 104 may be controlled and used by the same entity that operates computer 101. Remote server 104 represents the machine(s) that collect and store helpful and useful data for use by other computers, such as computer 101. For example, in a hypothetical case where computer 101 is designed and programmed to provide a recommendation based on historical data, then this historical data may be provided to computer 101 from remote database 130 of remote server 104.

Public cloud 105 is any computer system available for use by multiple entities that provides on-demand availability of computer system resources and/or other computer capabilities, especially data storage (cloud storage) and computing power, without direct active management by the user. Cloud computing typically leverages sharing of resources to achieve coherence and economies of scale. The direct and active management of the computing resources of public cloud 105 is performed by the computer hardware and/or software of cloud orchestration module 141. The computing resources provided by public cloud 105 are typically implemented by virtual computing environments that run on various computers making up the computers of host physical machine set 142, which is the universe of physical computers in and/or available to public cloud 105. The virtual computing environments (VCEs) typically take the form of virtual machines from virtual machine set 143 and/or containers from container set 144. It is understood that these VCEs may be stored as images and may be transferred among and between the various physical machine hosts, either as images or after instantiation of the VCE. Cloud orchestration module 141 manages the transfer and storage of images, deploys new instantiations of VCEs and manages active instantiations of VCE deployments. Gateway 140 is the collection of computer software, hardware, and firmware that allows public cloud 105 to communicate through WAN 102.

Some further explanation of virtualized computing environments (VCEs) will now be provided. VCEs can be stored as “images.” A new active instance of the VCE can be instantiated from the image. Two familiar types of VCEs are virtual machines and containers. A container is a VCE that uses operating-system-level virtualization. This refers to an operating system feature in which the kernel allows the existence of multiple isolated user-space instances, called containers. These isolated user-space instances typically behave as real computers from the point of view of programs running in them. A computer program running on an ordinary operating system can utilize all resources of that computer, such as connected devices, files and folders, network shares, CPU power, and quantifiable hardware capabilities. However, programs running inside a container can only use the contents of the container and devices assigned to the container, a feature which is known as containerization.

Private Cloud 106 is similar to public cloud 105, except that the computing resources are only available for use by a single enterprise. While private cloud 106 is depicted as being in communication with WAN 102, in other embodiments a private cloud may be disconnected from the internet entirely and only accessible through a local/private network. A hybrid cloud is a composition of multiple clouds of different types (for example, private, community or public cloud types), often respectively implemented by different vendors. Each of the multiple clouds remains a separate and discrete entity, but the larger hybrid cloud architecture is bound together by standardized or proprietary technology that enables orchestration, management, and/or data/application portability between the multiple constituent clouds. In this embodiment, public cloud 105 and private cloud 106 are both part of a larger hybrid cloud.

Cloud computing services and/or microservices (not separately shown in FIG. 1): private cloud 106 and public cloud 105 are programmed and configured to deliver cloud computing services and/or microservices (unless otherwise indicated, the word “microservices” shall be interpreted as inclusive of larger “services” regardless of size). Cloud services are infrastructure, platforms, or software that are typically hosted by third-party providers and made available to users through the internet. Cloud services facilitate the flow of user data from front-end clients (for example, user-side servers, tablets, desktops, laptops), through the internet, to the provider's systems, and back. In some embodiments, cloud services may be configured and orchestrated according to as “as a service” technology paradigm where something is being presented to an internal or external customer in the form of a cloud computing service. As-a-Service offerings typically provide endpoints with which various customers interface. These endpoints are typically based on a set of APIs. One category of as-a-service offering is Platform as a Service (PaaS), where a service provider provisions, instantiates, runs, and manages a modular bundle of code that customers can use to instantiate a computing platform and one or more applications, without the complexity of building and maintaining the infrastructure typically associated with these things. Another category is Software as a Service (SaaS) where software is centrally hosted and allocated on a subscription basis. SaaS is also known as on-demand software, web-based software, or web-hosted software. Four technological sub-fields involved in cloud services are: deployment, integration, on demand, and virtual private networks.

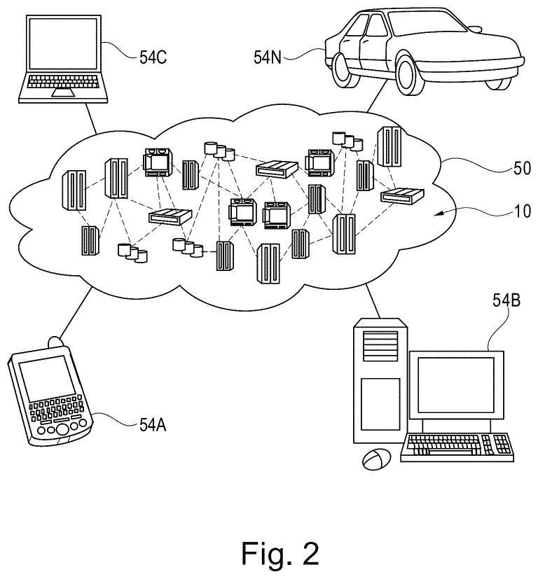

FIG. 2 It is to be understood that although this disclosure includes a detailed description on cloud computing, implementation of the teachings recited herein are not limited to a cloud computing environment. Rather, embodiments of the present invention are capable of being implemented in conjunction with any other type of computing environment now known or later developed.

Cloud computing is a model of service delivery for enabling convenient, on-demand network access to a shared pool of configurable computing resources (e.g., networks, network bandwidth, servers, processing, memory, storage, applications, virtual machines, and services) that can be rapidly provisioned and released with minimal management effort or interaction with a provider of the service. This cloud model may include at least five characteristics, at least three service models, and at least four deployment models.

Characteristics are as follows: On-demand self-service: a cloud consumer can unilaterally provision computing capabilities, such as server time and network storage, as needed automatically without requiring human interaction with the service's provider. Broad network access: capabilities are available over a network and accessed through standard mechanisms that promote use by heterogeneous thin or thick client platforms (e.g., mobile phones, laptops, and PDAs). Resource pooling: the provider's computing resources are pooled to serve multiple consumers using a multi-tenant model, with different physical and virtual resources dynamically assigned and reassigned according to demand. There is a sense of location independence in that the consumer generally has no control or knowledge over the exact location of the provided resources but may be able to specify location at a higher level of abstraction (e.g., country, state, or datacenter).

Rapid elasticity: capabilities can be rapidly and elastically provisioned, in some cases automatically, to quickly scale out and rapidly released to quickly scale in. To the consumer, the capabilities available for provisioning often appear to be unlimited and can be purchased in any quantity at any time. Measured service: cloud systems automatically control and optimize resource use by leveraging a metering capability at some level of abstraction appropriate to the type of service (e.g., storage, processing, bandwidth, and active user accounts). Resource usage can be monitored, controlled, and reported, providing transparency for both the provider and consumer of the utilized service. Service Models are as follows: Software as a Service (SaaS): the capability provided to the consumer is to use the provider's applications running on a cloud infrastructure. The applications are accessible from various client devices through a thin client interface such as a web browser (e.g., web-based e-mail). The consumer does not manage or control the underlying cloud infrastructure including network, servers, operating systems, storage, or even individual application capabilities, with the possible exception of limited user-specific application configuration settings.

Platform as a Service (PaaS): the capability provided to the consumer is to deploy onto the cloud infrastructure consumer-created or acquired applications created using programming languages and tools supported by the provider. The consumer does not manage or control the underlying cloud infrastructure including networks, servers, operating systems, or storage, but has control over the deployed applications and possibly application hosting environment configurations. Infrastructure as a Service (IaaS): the capability provided to the consumer is to provision processing, storage, networks, and other fundamental computing resources where the consumer is able to deploy and run arbitrary software, which can include operating systems and applications. The consumer does not manage or control the underlying cloud infrastructure but has control over operating systems, storage, deployed applications, and possibly limited control of select networking components (e.g., host firewalls).

Deployment Models are as follows: Private cloud: the cloud infrastructure is operated solely for an organization. It may be managed by the organization or a third party and may exist on-premises or off-premises. Community cloud: the cloud infrastructure is shared by several organizations and supports a specific community that has shared concerns (e.g., mission, security requirements, policy, and compliance considerations). It may be managed by the organizations or a third party and may exist on-premises or off-premises. Public cloud: the cloud infrastructure is made available to the general public or a large industry group and is owned by an organization selling cloud services. Hybrid cloud: the cloud infrastructure is a composition of two or more clouds (private, community, or public) that remain unique entities but are bound together by standardized or proprietary technology that enables data and application portability (e.g., cloud bursting for load-balancing between clouds). A cloud computing environment is service oriented with a focus on statelessness, low coupling, modularity, and semantic interoperability. At the heart of cloud computing is an infrastructure that includes a network of interconnected nodes.

Referring now to FIG. 2, illustrative cloud computing environment 50 is depicted. As shown, cloud computing environment 50 includes one or more cloud computing nodes 10 with which local computing devices used by cloud consumers, such as, for example, personal digital assistant (PDA) or cellular telephone 54A, desktop computer 54B, laptop computer 54C, and/or automobile computer system 54N may communicate. Nodes 10 may communicate with one another. They may be grouped (not shown) physically or virtually, in one or more networks, such as Private, Community, Public, or Hybrid clouds as described hereinabove, or a combination thereof. This allows cloud computing environment 50 to offer infrastructure, platforms and/or software as services for which a cloud consumer does not need to maintain resources on a local computing device. It is understood that the types of computing devices 54A-N shown in FIG. 2 are intended to be illustrative only and that computing nodes 10 and cloud computing environment 50 can communicate with any type of computerized device over any type of network and/or network addressable connection (e.g., using a web browser).

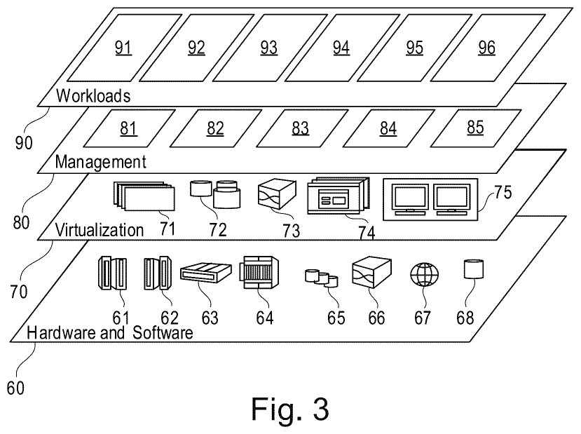

Referring now to FIG. 3, a set of functional abstraction layers provided by cloud computing environment 50 (FIG. 1) is shown. It should be understood in advance that the components, layers, and functions shown in FIG. 3 are intended to be illustrative only and embodiments of the invention are not limited thereto. As depicted, the following layers and corresponding functions are provided.

Hardware and software layer 60 includes hardware and software components. Examples of hardware components include mainframes 61; RISC (Reduced Instruction Set Computer) architecture based servers 62; servers 63; blade servers 64; storage devices 65; and networks and networking components 66. In some embodiments, software components include network application server software 67 and database software 68. The database software 68 may for example be used to implement the source database and the target database as described above.

Virtualization layer 70 provides an abstraction layer from which the following examples of virtual entities may be provided: virtual servers 71; virtual storage 72; virtual networks 73, including virtual private networks; virtual applications and operating systems 74; and virtual clients 75.

In one example, management layer 80 may provide the functions described below. Resource provisioning 81 provides dynamic procurement of computing resources and other resources that are utilized to perform tasks within the cloud computing environment. Metering and Pricing 82 provide cost tracking as resources are utilized within the cloud computing environment, and billing or invoicing for consumption of these resources. In one example, these resources may include application software licenses. Security provides identity verification for cloud consumers and tasks, as well as protection for data and other resources. User portal 83 provides access to the cloud computing environment for consumers and system administrators. Service level management 84 provides cloud computing resource allocation and management such that required service levels are met. Service Level Agreement (SLA) planning and fulfillment 85 provide pre-arrangement for, and procurement of, cloud computing resources for which a future requirement is anticipated in accordance with an SLA.

Workloads layer 90 provides examples of functionality for which the cloud computing environment may be utilized. Examples of workloads and functions which may be provided from this layer include mapping and navigation 91; software development and lifecycle management 92; virtual classroom education delivery 93; data analytics processing 94; transaction processing 95; and the implementation of a target database system 96 that uses an Electronic Design Automation system 400 as was described in the context of FIG. 1. In this example the target database system 96 may also provide data analytics processing.

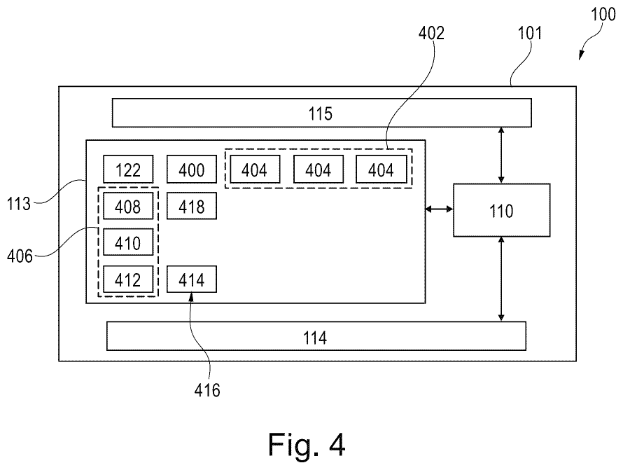

FIG. 4 shows a further view of the computing environment 100 that was detailed in FIG. 1. The persistent storage 113 is shown as storing additional data. Not all features present in FIG. 1 have been illustrated in FIG. 4. The memory or persistent storage 113 is again showing the implementation of the operating system 122. The persistent storage 113 also shows the software used to implement the Electronic Design Automation system 400. In addition to this, there is a logical design 402 that has been provided. The logical design 402 is for an integrated circuit and is comprised of multiple data sources 404. Together the data sources 404 make up the logical design 402. These data sources 404 have been parsed and used to construct an initial data structure 406 that comprises three groups of key value pairs 408, 410, and 412.

The key value pairs 408 are duplicate key value pairs and represent key value pairs which have more than one value associated to the same key which is parsable. The key value pairs labeled 410 represent utilized key value pairs and are key value pairs which only exist once, or which have been selected to be used for configuring the Electronic Design Automation system 400. The key value pairs 412 represent ignored key value pairs and are key value pairs 412 which will not be used for configuring the Electronic Design Automation system 400. The duplicate key value pairs 408 may have their conflicting values resolved by moving the duplicate key value pairs 408 into either the utilized key value pairs 410 or the ignored key value pairs 412. Typically, there may be several groups of key value pairs within the duplicate key value pairs 408. One of them would be assigned to the utilized key value pairs 410 and the rest would be assigned the ignored key value pairs 412. This can be performed in a variety of ways, for example using a rule-based system, an artificial intelligence, it could be referred to as an optional recommender algorithm 418. In other examples results from a graphical user interface may also be used to resolve the duplicate key value pairs 408.

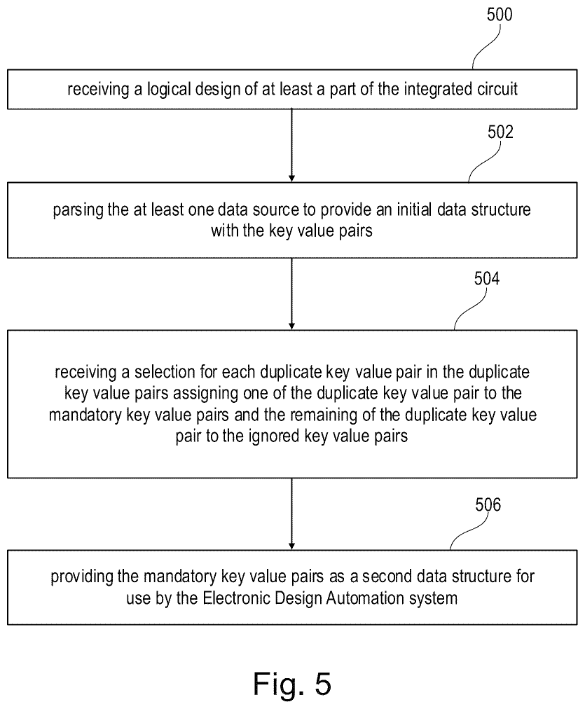

FIG. 5 shows a flowchart which illustrates a method of using the computing environment 100 of FIG. 4. In step 500 the logical design 402 is received. This logical design 402 represents at least a part of an integrated circuit. It could be an overall logical design, which would represent a complete design for the integrated circuit, or it just could be a portion of the integrated circuit, which is being run for test purposes. As was mentioned previously, the logical design 402 may be formed from multiple building blocks which could be macros used to represent sub-portions of different components of the integrated circuit.

The logical design 402 again is provided as a number of data sources 404. In step 502, the at least one data source 404 is parsed to provide the initial data structure 406. During the parsing the key value pairs are divided into the duplicate key value pairs 408, the utilized key value pairs 410, and the ignored key value pairs 412 to provide the initial data structure 406. In step 504, the duplicate key value pairs 408 are resolved. There is a selection received for each duplicate key value pair in the key value pairs 408 that assigns one of the duplicate key value pairs to the utilized key value pairs 410 and the rest to the ignored key value pairs 412. After this is finished, the utilized key value pairs 410 have been amended or modified to provide the amended utilized key value pairs 414. In step 506, the utilized key value pairs 414 are provided as a second data structure 416. This second data structure 416 may be used for properly configuring the Electronic Design Automation system 400.

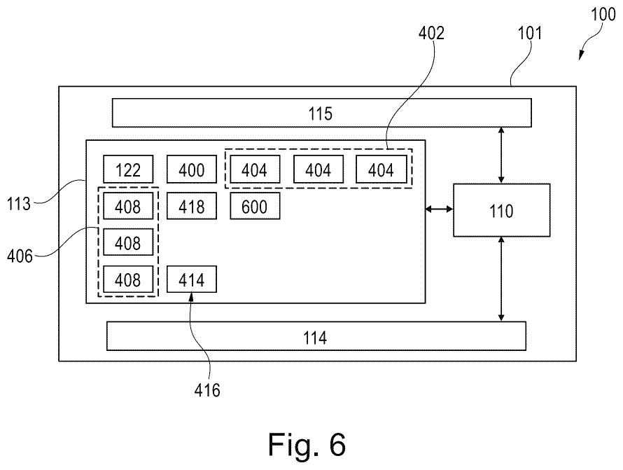

FIG. 6 illustrates a further example of the computing environment 100. In this example, the second data structure 416 has been used to configure the Electronic Design Automation system 400 to generate a physical integrated circuit design 600 using the logical design 402. This physical integrated circuit design 600 may then be used to directly manufacture an integrated circuit.

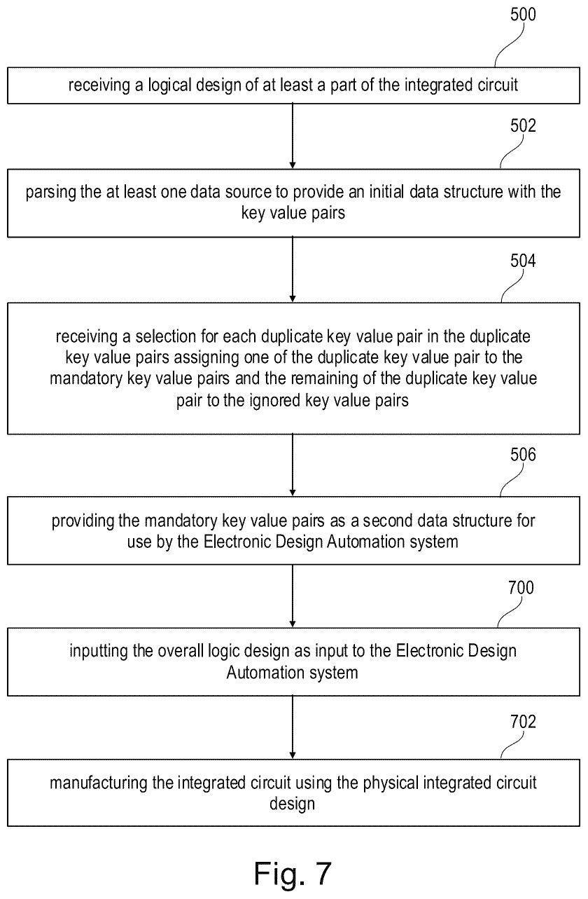

FIG. 7 shows a flowchart which illustrates a method of using the computing environment 100 illustrated in FIG. 6. Step 500, 502, 504, and 506 are performed as was illustrated in FIG. 5. Additionally, step 700 and 702 are performed. In step 700 the logical design 402 or overall logical design is input into the Electronic Design Automation system 400 using the second data structure 416 to configure it. This may for example be used to configure it directly or the data in the second data structure 416 is written back to the original data sources 404 making up the logical design 402. In step 702, the integrated circuit is manufactured using the physical integrated circuit design 600. This may for example entail ordering masks and sending the details of the physical integrated circuit design 600 to a manufacturing site or a fabrication site.

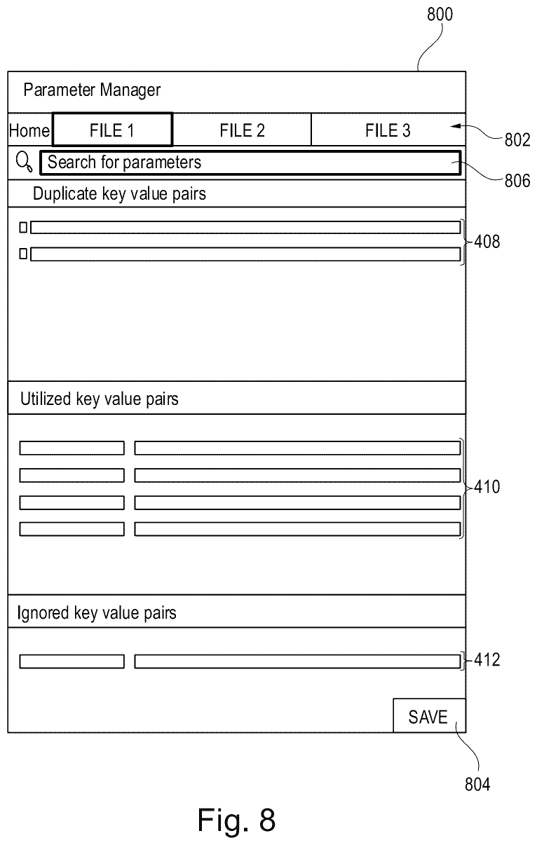

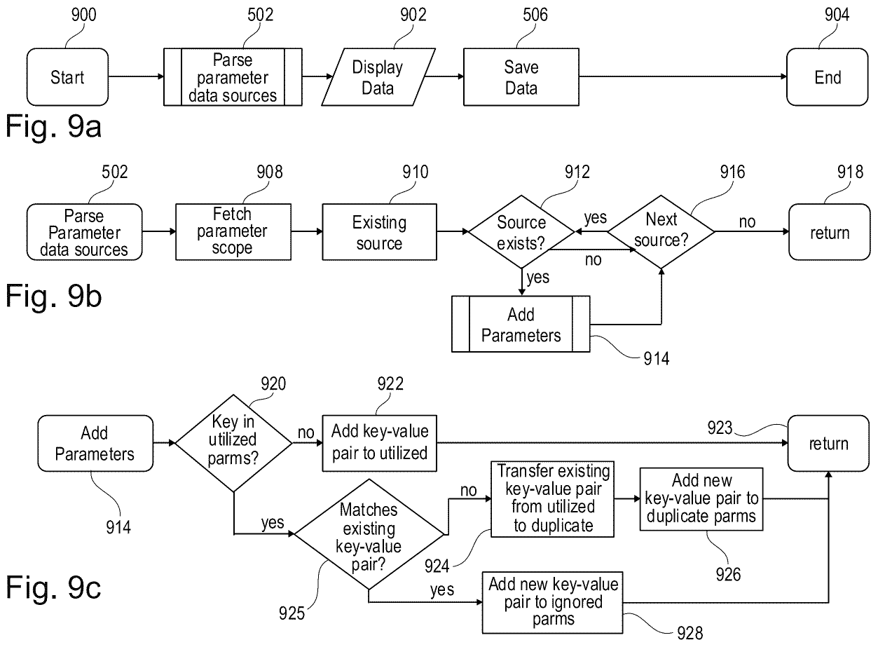

FIG. 8 illustrates an example of a user interface 800 used to display and edit the key value pairs. On this interface there is a region 802 which enables data source control. There are different ways of searching and parsing the key value pairs. FIG. 8, FIG. 9a, FIG. 9b, and FIG. 9c show an example, which has a data source-based hierarchical method, is examined. The region 802 enables the user to see which key value pairs come from which data source 404. The user interface 800 has a region for displaying the duplicate key value pairs 408, a region for displaying the utilized key value pairs 410, and a region for displaying the ignored key value pairs 412. The operator may, for example, be able to freely move the key value pairs into different groups and edit them and even in some examples add additional key value pairs that may be missing. This may be a useful tool for configuring the Electronic Design Automation system 400. The user interface 800 additionally comprises a search box 806 which may be configured to search for and entered string or value within the “keys” or “values” within the duplicate key value pairs 408, the utilized key value pairs 410, and the ignored key value pairs 412. The search functionality may be configured in different ways. In some examples search functionality may search for exact matches or in other cases it may also return similar “keys” or “values.” For example a trained neural network may be used to recognize “keys” or “values” which are similar but not identical to the entered string or value.

FIG. 9a shows a means of supplying the key value pairs 408, 410, and 412 for the user interface 800 in FIG. 8 using a data source-based parsing method. The method is illustrated in several different flowcharts. The top flowchart is the overall flowchart. The method starts in step 900 and in step 502, the data sources 404 are parsed for the key value pairs. In step 902, the initial data structure 406 is displayed using the user interface 800 illustrated in FIG. 8. The user may then edit it and save the data in step 506 providing for the second data structure 416. The method then ends in step 904. The second data structure 416 may also be used for configuring the Electronic Design Automation system 400 as was described above. Step 502 is now described in greater detail.

The second flowchart FIG. 9b represents step 502 where the parameter data sources are parsed. This is performed in a number of steps. The first is to fetch a parameter data source scope in step 908. This may for example determine a path to the individual data sources 404 or for configuration data associated with these data sources 404. In step 910, existing sources which may represent data structures or files where the key value pairs may be stored are looked for.

These are sources where the actual key value pairs are stored. There is a decision step 912 if the source exists. In some instances, there may be an existing source and in some cases it may although the path is determined pointing to a source, where no information is stored or pointing to a non-existing source, the source for the key value pairs may not exist. If the source does exist the method goes to step 914, which represents adding parameters or key value pairs to the initial data structure 406.

The method then proceeds from step 914 to step 916. In step 916 it is checked if there is another or next source where key value pairs can be parsed or harvested from. If the answer is yes, the method returns to step 912. In step 912 there is also the possibility that, although there was a path provided, there is no data to read. In this case the method proceeds to step 916. If there is no next source then from step 916, the method proceeds to step 918 and the method returns to the first flowchart and step 902 is performed.

The third flowchart FIG. 9c illustrates the parsing of parameters in step 914 from the second flowchart in FIG. 9b in more detail. The steps following step 914 illustrate how the various key value pairs can be sorted into the duplicate key value pairs 408, the utilized key value pairs 410, and the ignored key value pairs 412. In step 920, it is determined if a freshly parsed key value pair is present in the utilized key value pairs 410. If they are not, it is the no branch of the decision in step 920, then the newly parsed key value pair contains only values for these particular key value pairs and the key value pair is added to the utilized key value pairs 410 in step 922. Step 923 is then performed and the method returns to step 914 of the method of FIG. 9b.

Alternatively following the yes branch of the decision in step 920, if the key value pairs are present in the utilized key value pairs 410, decision step 925 is performed. The question in step 925 is does the value of the newly parsed key value pair match an existing key value pair. If it does not match—the no branch of step 925—then in step 924 the existing key value pairs are transferred from the utilized key value pairs 410 to the duplicate key value pairs 408. In step 926 the newly parsed key value pair is also copied to the duplicate key value pairs 408. The method then returns in step 920 to step 914 of the method of FIG. 9b. If in step 925—yes branch—the existing key value pair matches an existing key value pair, the method proceeds to step 928 and the newly parsed key value pair is added to the ignored key value pairs. After this the method returns back in step 920 to step 914 of FIG. 9b.

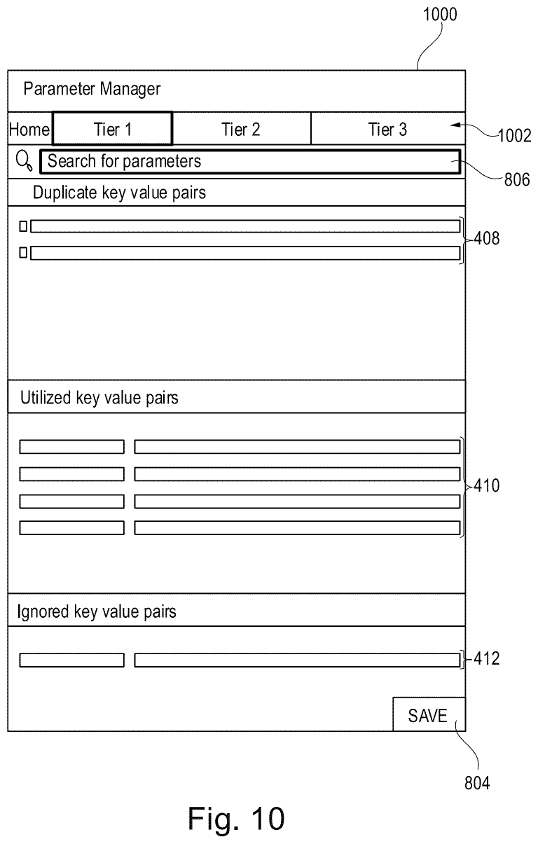

FIG. 10 illustrates a further example of a user interface 1000, which may be used to edit and adapt the initial data structure 406. The user interface 1000 is similar to the user interface 800 except that instead of a data source-based manipulation of them, the key value pairs are assigned using a precedence level. There is a precedence level control interface 1002 which enables the selection of several different precedence level tiers. By clicking on the different precedence level tiers in the precedence level control interface 1002. In one example the precedence level tiers could represent individual precedence levels and the different parameters according to precedence level can be displayed. In another example, the precedence level tiers are populated with the key value pairs with the highest precedence level. The precedence level tiers are discussed in greater detail below. Both examples provide a precedence level-based parameter management system. An advantage of this is displaying parameters according to precedence levels may provide for better consistency across parameter data sources and reduces the risk of unexpected tool behavior.

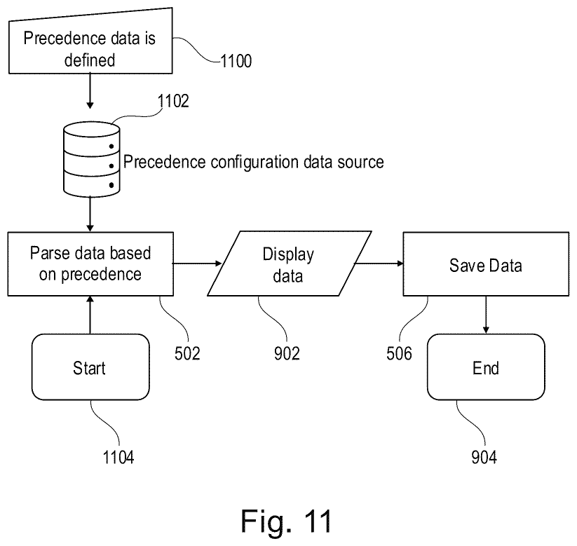

FIG. 11 shows a flowchart which illustrates a method of supplying the key value pairs for the user interface 1000 of FIG. 10. The method is broken into two steps. In step 1100 the precedence level for the key value pairs is defined and then stored in a precedence configuration data source 1102. In this particular example, the precedence level is used to determine the hierarchy of the key value pairs by assigning a numerical precedence level. The second method starts with step 1104 and the method proceeds to step 502 where the key value pairs are parsed based on the precedence values in the precedence configuration data source 1102. In step 902, the data is displayed using the user interface 1000 and the user may then operate on and manipulate the data using the user interface 1000. After this, the user clicks on control 804 and saves the data in step 506, thereby providing the second data structure 416. The method then ends in step 904.

As an example, in particular with respect to the user interface 800 and user interface 1000 illustrated in FIGS. 8 and 10, is discussed. Initially the behaviors of a typical Electronic Design Automation (EDA) system is discussed.

Two exemplary parameter data sources are considered: parameter file A and parameter file B. The data sources and their key values are listed below.

Parameter file A (Precedence level=4): Parameter_A: value_1; Parameter_B: value_2; Parameter_D: value_6; Parameter file B (Precedence level=2); Parameter_A: value_3; Parameter_B: value_4; Parameter_C: value_5.

Initially, the EDA tool loads the data from parameter file A: Parameter_A: value_1; Parameter_B: value_2; Parameter_D: value_6.

The parameter file A data source is described above has having a higher precedence level than parameter file B (4 vs 2). The data from parameter file B and parameter file A are both loaded and are merged. In case of conflicts, the value from parameter file A wins because of the precedence level of the respective data source. The merged key value pairs are shown below: Parameter_A: value_1 (Loaded and overwritten with the value from parameter file A); Parameter_B: value_2 (Loaded and overwritten with the value from parameter file A); Parameter_C: value_5 (Added from parameter file B); Parameter_D: value_6 (Loaded and overwritten with the value from parameter file A).

The key value pairs that would then be used by the EDA system will be: Parameter_A: value_1 (from parameter file A); Parameter_B: value_2 (from parameter file A); Parameter_C: value_5 (from parameter file B); Parameter_D: value_6 (from parameter file A).

In one example, the user does not want to set Parameter_A, so the user removes it from parameter file A: Parameter file A (Precedence level=4); Parameter_A: value_1 (removed); Parameter_B: value_2; Parameter_D: value_6; Parameter file B (Precedence level=2); Parameter A: value 3 (Now fetched from parameter file B); Parameter B: value 4; Parameter C: value 5.

However, the user might forget or be unaware that that Parameter_A was also set in a source data source with the lower precedence value (in parameter file B). Now, although the user did not want to set the value for Parameter_A, it is nonetheless fetched from parameter file B.

The set of key values to configured the EDA system would then be: Parameter_A: value_3 (from parameter file B); Parameter_B: value_2 (from parameter file A); Parameter_C: value_5 (from parameter file B); Parameter_D: value_6 (from parameter file A).

One sees that the value for Parameter_A is used from parameter file B, the data source with the lower precedence value. This illustrates potential problems when configuring an EDA system using key values read from multiple data sources.

The user interface 800 and user interface 1000 help to avoid this problem, because they display the set of key values which will be eventually used (the utilized key value pairs).

Furthermore, in some examples the collected key value pairs (represented in the actual state saved in the data source system) could be saved as a snapshot. In some examples, this snapshot could be saved and applied to the same Electronic Design Automation system or even potentially used by a different Electronic Design Automation system or for a different integrated circuit synthesis project.

Another example where value conflicts and their resolution are explored. In this example it is assumed we only have one parameter source with the following data: Parameter file B: Parameter_A: value_1; Parameter_B: value_2; Parameter_C: value_3; Parameter_A: value_4.

Examining the above, one can see that there's obviously a conflict for Parameter_A which is listed twice and is an example of a duplicate key value pair: Parameter_A: value_1; Parameter_A: value_4.

One question now is, which value for Parameter_A will be used by the Electronic Design Automation system? This may be indeterminate and potentially the Electronic Design Automation System can behave differently from synthesis run to run. In this case, one would expect non-deterministic or non-obvious behavior, which is a non-desired property.

Examples as described herein may detect the duplicate key values with different values as well as unique key-value pairs. In this example, the above indeterminate behaviors of the Electronic Design Automation system is resolved by placing Parameter_A into the duplicate key value pairs: Parameter_A: value 1→(sorted to the duplicate key value pairs 408); Parameter B: value 2→(sorted to the utilized key value pairs 410); Parameter_C: value 3→(sorted to the utilized key value pairs 410); Parameter_A: value 4→(sorted to the utilized key value pairs 408).

In the user interface 800 and user interface 1000, the user may resolve the conflict before storing the parameters back in the data source or using them directly to control the Electronic Design Automation system 400. Note: In this case, just one parameter data source is examined.

Now, one may consider the following parameter set to better understand how different data sources can lead to non-obvious parameter conflicts which impact the Electronic Design Automation system 400 behavior: Parameter file C (Precedence level=4); Parameter_A: value_1; Parameter_D: value_6; Parameter file D (Precedence level=4); Parameter_A: value_7; Parameter_C: value_4; Parameter_E: value_8; Parameter file E (Precedence level=2); Parameter_A: value_3; Parameter_B: value_4; Parameter_C: value_5.

In this example parameter file C and parameter file D have the same precedence level (4), which is higher than the precedence level from parameter file E (2). When the key value pairs are loaded, data loaded from parameter file C and parameter file D overwrite data loaded from parameter file E.

When the data is loaded there is a conflict for Parameter_A which is loaded from both parameter file C and parameter file D. Parameter_A: value_1 (conflict-value of Parameter_A from parameter file C); Parameter_A: value_7 (conflict-value of Parameter_A from parameter file D); Parameter_B: value_4 (from parameter file E); Parameter_C: value_4 (from parameter file D); Parameter_D: value_6 (from parameter file C); Parameter_E: value_8 (from parameter file D).

The set of parameters are fetched from different sources (in this example, three parameter data sources) based on the parameter precedence levels. Although there is no key-value conflict within the same data source, a new conflict occurs when merging the data (which is, in fact, the set of parameters that the Electronic Design Automation system would “receive”). To address this issue, the same method on this parameter set is applied, like in the single data source approach, which we discussed before. In this scenario, the user interface 800 and user interface 1000 would display the following classification:

Duplicate key value pairs (408): Parameter_A: value_1 (from parameter file C) and Parameter_A: value_7 (from parameter file D).

Utilized key value pairs (410): Parameter_B: value_4 (from parameter file E); Parameter_C: value_4 (from parameter file D); Parameter_D: value_6 (from parameter file C); Parameter_E: value_8 (from parameter file D).

Again, the user may resolve the key-value conflict using the user interface 800 and user interface 1000 before saving the data back into the data source system.

In a further example, the utility of the ignored key value pairs 412 portion of the user interface 800 and user interface 1000 is described.

The following parameter data source is given: Parameter file E: Parameter_A: value_1; Parameter_B: value_2; Parameter_C: value_3; Parameter_A: value_7; Parameter_C: value_3.

In examples one preferably has each element just once in a parameter data source. When parsing the data source, it is detected that the exact same key-value pair is present in the same data source multiple times: Parameter_A: value_1 (duplicate not yet detected); Parameter_B: value_2 (no conflict); Parameter_C: value_3 (duplicate not yet detected); Parameter_A: value_7 (duplicate values for Parameter_A detected); Parameter_C: value_3 (duplicate values for Parameter_A detected).

The parameter in line 5 can be deleted without changing the information of the data source. The parameter from line 5 would be temporarily saved as “ignored key value pairs 412” and displayed in the user interface 800 and user interface 1000 to make the user aware of the deletion. With this approach, parameter data sources are determined, and the data overhead may be reduced. As the duplicate value for Parameter_C has the same value in line 3 and 5 a reduction may be possible. Technically, one does not need to actively delete these key value pairs, they could just not be saved back into the data source. Having the exact same key-value pair in different data sources is another edge case, which one can address in different ways. The user can change the individual key-value pairs, the user can change one key-value pair, and the change is applied to all data sources. The user may decide which key-value pair should be kept (the other ones would be deleted or ignored).

Besides a fixed precedence level, one could alternatively introduce a dynamic precedence level sorting system, which distinguishes between “current parameters,” “next parameters,” “next-next parameters,” etc. The following example visualizes how this dynamic parameter precedence level sorting system for key value pairs could be implemented.

One may also consider the following parameter sources with different precedence levels: Source 1 (Precedence level=3): Parameter_A: value_1; Parameter_B: value_2; Parameter_C: value_3. Source 2 (Precedence level=2): Parameter_C: value_4; Parameter_D: value_5; Parameter_E: value_6. Source 3 (Precedence level=1): Parameter_E: value_7; Parameter_F: value_8; Parameter_G: value_9.

The user interface 1000 would display the following sections with the respective parameter sets.

In a first precedent level tier the utilized key value pairs 410 where the key value pairs with a higher precedent level are selected if there are duplicates and then those will be used by the electronic design automation system: Parameter_A: value_1 (Source 1); Parameter_B: value_2 (Source 1); Parameter_C: value_3 (Source 1); Parameter_D: value_5 (Source 2); Parameter_E: value_6 (Source 2); Parameter_F: value_8 (Source 3); Parameter_G: value_9 (Source 3).

The duplicate key value pairs are displayed in a second tier. They are selectable using the precedence level control interface 1002 of the user interface 1000. The values are then: Parameter_C: value_4 (Source 2) and Parameter_E: value_7 (Source 3).

One can see that the parameters of all three sources are used by the EDA system. In the set of parameters, values from sources 2 and 3 are assigned to the (dynamic) second precedence level, although they have the “static” precedence of 2 and 1

The descriptions of the various embodiments of the present invention have been presented for purposes of illustration, but are not intended to be exhaustive or limited to the embodiments disclosed. Many modifications and variations will be apparent to those of ordinary skill in the art without departing from the scope of the described embodiments. The terminology used herein was chosen to best explain the principles of the embodiments, the practical application or technical improvement over technologies found in the marketplace, or to enable others of ordinary skill in the art to understand the embodiments disclosed herein.

1. A method comprising:
receiving a logical design of at least a part of an integrated circuit, wherein the logical design includes multiple building blocks with key value pairs, wherein the logical design is provided in at least one data source;
parsing the at least one data source to provide an initial data structure with the key value pairs, wherein the initial data structure provides the key value pairs divided into duplicate key value pairs, utilized key value pairs, and ignored key value pairs;
assigning, for each duplicate key value pair in the duplicate key value pairs, a first portion of duplicate key value pairs to the utilized key value pairs and a remaining portion of the duplicate key value pairs to the ignored key value pairs; and
providing the utilized key value pairs as a second data structure.

2. The method of claim 1, wherein providing the utilized key value pairs further comprises:
storing the utilized key value pairs from the second data structure back to the at least one data source of the logical design or by using the second data structure to at least partially override a configuration.

3. The method of claim 1, wherein the assigning, for each duplicate key value pair in the duplicate key value pairs, the first portion of duplicate key value pairs to the utilized key value pairs and the remaining portion of the duplicate key value pairs to the ignored key value pairs is at least partially provided by a recommender algorithm.

4. The method of claim 1, wherein the assigning, for each duplicate key value pair in the duplicate key value pairs, the first portion of duplicate key value pairs to the utilized key value pairs and the remaining portion of the duplicate key value pairs to the ignored key value pairs is at least partially received from a graphical user interface that displays the duplicate key value pairs, utilized key value pairs, and ignored key value pairs.

5. The method of claim 1, further comprising:
storing a selection of the key value pairs in a database or a file system in response to receiving the selection of the key value pairs from a graphical user interface.

6. The method of claim 1, wherein the parsing of the at least one data source to provide the initial data structure with the key value pairs comprises comparing the key value pairs to a precedence configuration data structure.

7. The method of claim 1, wherein the parsing of the at least one data source to provide the initial data structure with the key value pairs further comprises:
fetching a parameter scope for the at least one data source;
constructing a path to look for parameter data structures for the parameter scope for the at least one data source;
adding key value parameters from the parameter data structures if the parameter data structures exist, wherein unique key value parameters of the parameter data structures are added to the utilized key value pairs, wherein duplicate key value parameters of the parameter data structures are added to the ignored key value pairs, wherein one of a matching pre-existing key value pair in the utilized key value pairs and a newly parsed pre-existing key value pair of the parameter data structures is assigned to the duplicate key value pairs and another of the matching is assigned to the duplicate key value pairs; and
proceeding to a next data source of the at least one data source if the parameter data structures does not exist.

8. The method of claim 7, wherein the parameter data structures have a hierarchy, wherein the hierarchy of the one of the matching pre-existing key value pair in the utilized key value pairs and a newly parsed pre-existing key value pair with a higher hierarchy is assigned to the utilized key value pairs.

9. The method of claim 1, wherein assigning, for each duplicate key value pair in the duplicate key value pairs, the first portion of duplicate key value pairs to the utilized key value pairs and the remaining portion of the duplicate key value pairs to the ignored key value pairs further comprises:
analyzing at least one data source to sort the key value pairs into the duplicate key value pairs, the utilized key value pairs, and the ignored key value pairs.

10. The method of claim 9, further comprising:
extracting the key value pairs from multiple data sources, wherein the at least one data source is the multiple data sources; and
sorting the multiple data sources based on the analyzing the at least one data source to sort the key value pairs.

11. The method of claim 9, wherein the analyzing the at least one data source to sort the key value pairs further comprises:
identifying if at least two different parameter sets have been created with a similar parameter set for same or a different building block of the multiple building blocks.

12. The method of any one of claims 9, wherein the analyzing the at least one data source to sort the key value pairs further comprises:
identifying and resolving possible conflicts between different key value parameters sets belonging to a similar building block of the multiple building blocks.

13. The method of claim 1, further comprising:
generating a preliminary physical design of a critical signal path;
utilizing the second data structure during generation of the preliminary physical design, wherein the logical design of the at least a part of the integrated circuit is a critical signal path of an overall logical design of the integrated circuit; and
providing the preliminary physical design of the critical signal path.

14. The method of claim 13, wherein the logical design of the at least a part of the integrated circuit is an overall logical design of the integrated circuit.

15. The method of claim 14, further comprising:
generating a physical integrated circuit design by inputting the overall logical design as input; and
utilizing the second data structure during generation of the physical integrated circuit design, wherein the preliminary physical design is preferably used as the input during generation of the physical integrated circuit design.

16. The method of claim 15, further comprising:
manufacturing the integrated circuit using the physical integrated circuit design.

17. The method of claim 1, further comprising:
flattening the multiple building blocks during parsing of the at least one data source.

18. The method of claim 1, wherein providing the second data structure is performed by a separate software tool.

19. A computer program product comprising:
one or more computer-readable storage media; and
program instructions stored on the one or more computer-readable storage media to perform operations comprising:
receiving a logical design of at least a part of an integrated circuit, wherein the logical design includes multiple building blocks, wherein the logical design is provided in at least one data source, wherein the multiple building blocks include key value pairs;
parsing the at least one data source to provide an initial data structure with the key value pairs, wherein the initial data structure provides the key value pairs divided into duplicate key value pairs, utilized key value pairs, and ignored key value pairs;
assigning, for each duplicate key value pair in the duplicate key value pairs, a first portion of duplicate key value pairs to the utilized key value pairs and a remaining portion of the duplicate key value pairs to the ignored key value pairs; and
providing the utilized key value pairs as a second data structure.

20. A computer system comprising:
a processor set;
one or more computer-readable storage media; and
program instructions stored on the one or more computer-readable storage media to cause the processor set to perform operations comprising:
receiving a logical design of at least a part of an integrated circuit, wherein the logical design includes multiple building blocks, wherein the logical design is provided in at least one data source, wherein the multiple building blocks include key value pairs;
parsing the at least one data source to provide an initial data structure with the key value pairs, wherein the initial data structure provides the key value pairs divided into duplicate key value pairs, utilized key value pairs, and ignored key value pairs;
assigning, for each duplicate key value pair in the duplicate key value pairs, a first portion of duplicate key value pairs to the utilized key value pairs and a remaining portion of the duplicate key value pairs to the ignored key value pairs; and
providing the utilized key value pairs as a second data structure.
